(19) United States
(12) Patent Application Publication
(10) Pub. No.: US 2020/0185930 A1
(43) Pub. Date: Jun. 11, 2020

(54) ELECTRIC STORAGE MODULE AND ELECTRIC STORAGE MODULE RAPID CHARGING SYSTEM

(71) Applicants: KUWATA CO., LTD., Chiba (JP); NIPPON LSA INC., Tokyo (JP); POWDEC K.K., Tochigi (JP); INSTITUTE FOR ENERGY APPLICATION TECHNOLOGIES. CO., LTD., Tochigi (JP)

(72) Inventors: Tsutomu Kuwata, Chiba (JP); Teruo Ogawa, Tokyo (JP); Hiroji Kawai, Tochigi (JP); Tomio Sugano, Tochigi (JP)

(21) Appl. No.: 16/349,569

(22) PCT Filed: Nov. 14, 2017
(86) PCT No.: PCT/JP2017/040860

§ 371 Date: May 13, 2019

(30) Foreign Application Priority Data
Nov. 15, 2016 (JP) 2016-222441

(51) Int. Cl. H02J 7/00; H02J 7/35; H02J 7/34; H02J 7/02; H01L 29/20; H01L 23/367

(52) U.S. Cl. CPC H02J 7/0013; H02J 7/35; H01L 23/367; H02J 7/02; H01L 29/2003; H02J 7/345

(57) ABSTRACT

According to the present invention, a quick charging control means is provided with a power semiconductor which comprises a sapphire substrate and a gallium nitride power transistor that is formed on the sapphire substrate; and a heat dissipation means, which dissipates heat generated during the electric power conversion in the quick charging control means, is bonded to the element outer surface of the gallium nitride power transistor. In one embodiment of the present invention, the power semiconductor employs polarization super junction. In another embodiment of the present invention, the heat dissipation means is connected to at least one of a source region and a drain region in the element outer surface of the gallium nitride power transistor, and extends in the direction away from the sapphire substrate.

### TECHNICAL FIELD

The present invention relates to an electric storage module comprising a rapid charger and electric storage means and an electric storage module rapid charging system for rapidly charging the electric storage module.

### BACKGROUND ART

In recent years, various rechargeable electronic instruments such as electric power tools have seen increased use with the advancement in lithium ion battery technology. While these electronic instruments are generally charged using a household power source, i.e., alternating current power, it would be convenient if such electronic instruments can be charged in a short period of time outdoors or other places where a household power source is unavailable. In this regard, a technology for supplying power stored in an electric storage apparatus to a load has been proposed as an example of charging technology (see, for example, Patent Literature 1). The electric storage apparatus in Patent Literature 1 can rapidly charge a secondary battery while preventing deterioration of the secondary battery by using the secondary battery in conjunction with a capacitor.

### CITATION LIST

### Patent Literature

[PTL 1] Japanese Laid-Open Publication No. 2015-12751

### SUMMARY OF INVENTION

### Technical Problem

Charging of lithium ion batteries have entailed problems such as long charging time that make charging inconvenient. For example, if mobile entities for communication such as smartphones and personal computers can be charged in a short period of time such as several minutes, this would be very convenient and improve the operational efficiency. However, drastic reduction of charging time entails problems. For example, rapid charging control using a conventional power controlling semiconductor leads to an increase in the size of a power conversion unit, so that it is difficult to incorporate a function for rapid charging into a smartphone, a personal computer, or the like.

Currently, various industrial instruments are rapidly developed as electrically powered instruments for the improvement of the environment, and if the size of a rapid charger can be reduced significantly, operational efficiency can be improved. Therefore, there is a demand for the development of a novel electric storage module directed thereto.

In this regard, the objective of the present invention is to provide an electric storage module, which can have a rapid charger with a significantly reduced size, and an electric storage module rapid charging system for rapidly charging the electric storage module.

### Solution to Problem

An electric storage module according to one embodiment of the invention comprises first electric storage means and first rapid charging control means, which has a power semiconductor for power conversion and applies power conversion on externally supplied power to rapidly charge the first electric storage means, wherein the power semiconductor comprises a sapphire substrate and a gallium nitride power transistor formed on the sapphire substrate, and wherein heat dissipating means for dissipating heat generated by power conversion in the first rapid charging control means is bound to an outer surface of an element of the gallium nitride power transistor. The aforementioned objective is achieved therewith.

The invention according to this embodiment can significantly reduce the size of the first rapid charging control means by employing a power semiconductor comprising a sapphire substrate and a gallium nitride power transistor.

In one embodiment, the power semiconductor is a power semiconductor employing polarization super junction.

In one embodiment, the heat dissipating means is connected to at least one of a source region and a drain region on the outer surface of an element of the gallium nitride power transistor and extends in a direction away from the sapphire substrate.

In one embodiment, the first rapid charging control means is configured to be capable of controlling a voltage and a current for rapid charging which takes into account a charging property of the first electric storage means by an integral design with the first electric storage means.

In one embodiment, the first electric storage means comprises at least one of a lithium ion battery, an electric double layer capacitor, and a lithium ion capacitor.

In one embodiment, the first rapid charging control means has artificial intelligence for optimally controlling a charging condition of the first electric storage means based on a charging history of the first electric storage means.

In one embodiment, the first electric storage means and the first rapid charging control means are configured to be integrated into at least electrically powered mobile entities including vehicles or mobile entities for communication including mobile phones.

In one embodiment, the electric storage module further comprises a power converter for adjusting and outputting a voltage of direct current power that is outputted from the first electric storage means.

An electric storage module rapid charging system according to one embodiment of the invention comprises the electric storage module and a power storage apparatus having second electric storage means which is electrically connectable to the electric storage module, wherein the power storage apparatus is configured to be able to supply power, when connected to the electric storage module, from the second electric storage means to the electric storage module. The aforementioned objective is achieved therewith.

In one embodiment, the second electric storage means of the power storage apparatus has a greater electric storage capacity than the first electric storage means, and is capable of simultaneously charging a plurality of the electric storage modules with direct current power outputted from the second electric storage means.

In one embodiment, power stored in the power storage apparatus is power generated using renewable energy.

### Advantageous Effects of Invention

The present invention enables switching at high speeds compared to conventional semiconductors using silicon, and materializes reduction in size of parts constituting an electric circuit for operating a power semiconductor, resulting in significant reduction in size of first rapid charging control means. Furthermore, heat dissipating means for dissipating heat is bonded to an outer surface of an element of a gallium nitride power transistor, thus promoting the dissipation of heat generated by power conversion in the first rapid charging control means to enable reduction in size of the configuration for cooling the gallium nitride power transistor. In this manner, the size of first rapid charging control means can be significantly reduced in an electric storage module. Therefore, an electric storage module can be readily integrated into various products to improve the usability of products and operational efficiency.

### BRIEF DESCRIPTION OF DRAWINGS

FIG. 1 is a wiring diagram schematically depicting the electric storage module according to embodiment 1 of the invention.

FIG. 2 is a wiring diagram depicting the details of a forced cooling structure in the electric storage module of FIG. 1.

FIG. 3 is an expanded cross-sectional view of a power semiconductor in the electric storage module of FIG. 1.

FIG. 4 is a perspective view of the main parts of the power semiconductor in FIG. 4.

FIG. 5 is a cross-section view along line A-A in FIG. 4.

FIG. 6 is an expanded cross-sectional view of the main parts of the power semiconductor in FIG. 3.

FIG. 7 is a wiring diagram schematically depicting an electric storage module rapid charging system for rapidly charging an electric car incorporating the electric storage module according to embodiment 2 of the invention.

FIG. 8 is a wiring diagram schematically depicting the power storage apparatus in FIG. 7.

FIG. 9 is a perspective view schematically depicting a personal computer incorporating the electric storage module according to embodiment 3 of the invention.

FIG. 10 is a wiring diagram schematically depicting a power storage apparatus for rapidly charging the personal computer in FIG. 9.

FIG. 11 is a perspective view schematically depicting a smartphone incorporating the electric storage module according to embodiment 4 of the invention.

FIG. 12 is a schematic diagram of an electric power tool incorporating the electric storage module according to embodiment 5 of the invention.

FIG. 13 is a schematic diagram of an electric storage module rapid charging system, depicting the electric storage module according to embodiment 6 of the invention when used as a portable electric storage module.

FIG. 14 is a schematic diagram depicting the electric storage module in FIG. 13 when used as a power source for air conditioned clothing.

FIG. 15 is a schematic diagram depicting simultaneous rapid charging of a plurality of the electric storage modules according to embodiment 7 of the invention.

FIG. 16 is an expanded cross-sectional view of a conventional power semiconductor using a gallium nitride element.

### DESCRIPTION OF EMBODIMENTS

The embodiments of the invention are now explained in detail with reference to the drawings.

### Embodiment 1

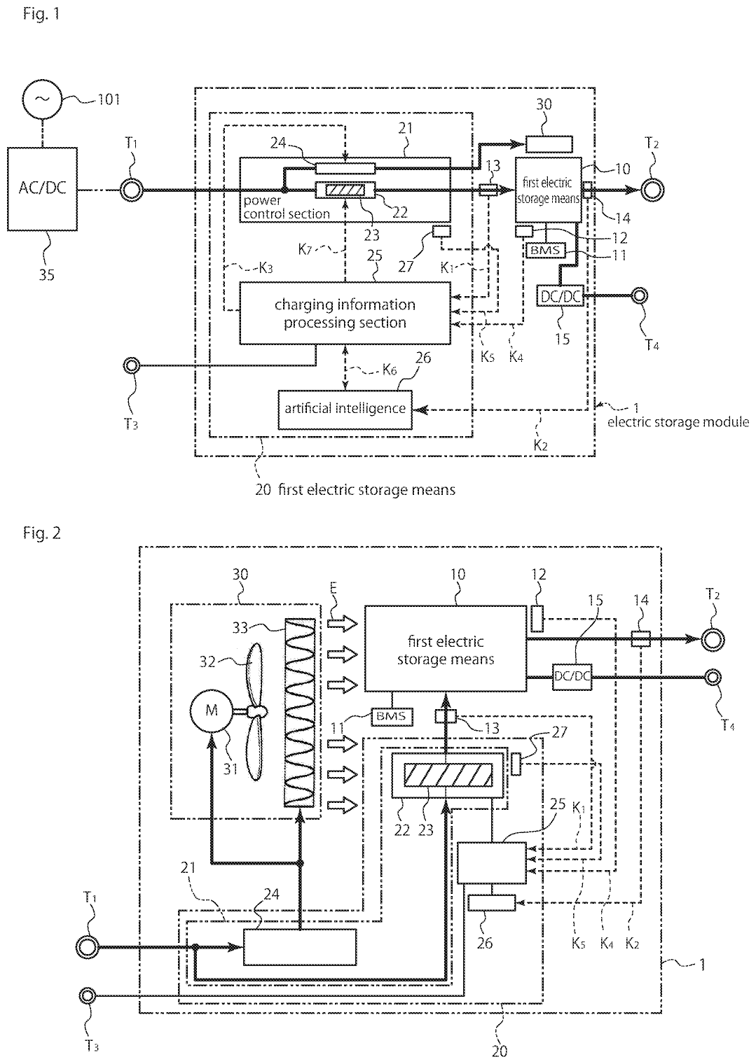

FIGS. 1 to 6 depict embodiment 1 of the invention. In FIG. 1, symbol 101 indicates an alternating current power source as a household power source. For example, a single phase alternating current power source is used as the alternating current power source 101. Alternating current power from the alternating current power source 101 is supplied to a power converter 35. The power converter 35 has a function of converting alternating current power to direct current power, and is comprised of, for example, an AC-DC converter. An AC-DC converter has a function of converting alternating current power inputted by switching control to direct current power. An AC-DC converter is made by utilizing a GaN (gallium nitride) semiconductor element because the efficiently of converting alternating current power to direct current power is enhanced thereby. Since a GaN semiconductor element is heat resistant, the structure for cooling the AC-DC converter can be simplified or eliminated.

As shown in FIG. 1, the power converter 35 is configured so that an input terminal T₁ of an electric storage module 1 can be connected. The electric storage module 1 has first electric storage means 10 and first rapid charging control means 20. Various instruments are installed in the electric storage module 1 in addition to the first electric storage means 10 and the first rapid charging control means 20. Direct current power supplied to the electric storage module 1 via the input terminal T₁ is controlled to have a predetermined voltage and current by the first rapid charging control means 20 and is then supplied to the first electric storage means 10. The first rapid charging control means 20 may be configured to be capable of controlling a voltage and a current for rapid charging which takes into account the charging property of the first electric storage means 10 by an integral design with the first electric storage means 10. If such controlling is enabled, the charging property of the first electric storage means 10 can be sufficiently taken into account by the integral design. Thus, charging can be controlled with a high level of precision, and the lifespan of the first electric storage means 10 can be extended, and better safety can be ensured. While the first electric storage means 10 can be any type of means as long as the means has a function that is capable of storing direct current power, the means is comprised of at least one of a rechargeable battery, an electric double layer capacitor, and a lithium ion capacitor in embodiment 1. The first electric storage means 10 in embodiment 1 is comprised of, for example, only a lithium ion battery configured as a large number of cells connected in series (including all-solid state batteries), but can have a configuration using a lithium ion battery in conjunction with a double layer capacitor or a lithium ion capacitor. Direct current power stored in the first electric storage means 10 can be supplied to a load (not shown) via an output terminal T₂. A first battery management system (BMS) 11 for maintaining the charging balance of a large number of cells constituting the first electric storage means 10 is connected to the first electric storage means 10.

When integrating the electric storage module 1 into an electrically powered mobile entity such as an electric car that is capable of recovering regenerative energy generated by braking, the variation in voltage on the output terminal T₂ side can be further minimized by employing a configuration using the first electric storage means 10 in conjunction with a lithium ion battery and a lithium ion capacitor, relative to a configuration using only a lithium ion battery. This is because most of the current that enters and leaves due to charging or discharging of the first electric storage means 10 from acceleration or deceleration upon operating a vehicle enters or leaves from a lithium ion capacitor, so that the amount of energy that enters and leaves the lithium ion battery decreases. Therefore, load on a lithium ion battery can be reduced to extend the lifespan of the first electric storage means 10 by employing a configuration using the first electric storage means 10 in conjunction with a lithium ion battery and a lithium ion capacitor.

A power converter 15 comprised of a DC-DC converter is connected to the first electric storage means 10. Direct current power outputted from the first electric storage means 10 can have the voltage adjusted by the power converter 15. A voltage adjusting switch (not shown) is connected to the power converter 15, such that a voltage in accordance with the application can be outputted from an output terminal T₄. This enables a supplied voltage to be adjusted to an optimal value that is in alignment with the type or function of an electronic instrument, and enables the use of the maximum capability of the electronic instrument. The temperature of the first electric storage means 10 can be detected by a first temperature sensor 12. An output signal K₄ from the first temperature sensor 12 is inputted into a charging information processing section 25. The temperature of a power control section 21 can be detected by a second temperature sensor 27. An output signal K₅ from the second temperature sensor 27 is inputted into the charging information processing section 25.

The first rapid charging control means 20 has the power control section 21 and the charging information processing section 25. The power control section 21 is comprised of a charging control unit 22 and a temperature control unit 24. The charging control unit 22 has a rapid charging control function for controlling direct current power from the power converter 35 to a charging voltage and charging current that are compatible with the first electric storage means 10. The charging control unit 22 has a direct current chopper circuit (direction current chopper circuit using a step-up chopper circuit in conjunction with a step-down chopper circuit) and a current controlling circuit. The charging control unit 22 has a function of controlling direct current power supplied from the power converter 35 with a chopper based on a control signal K₇ from the charging information processing section 25, and charging the first electric storage means 10 at an optimal charging voltage. A voltage and current outputted from the charging control unit 22 to the first electric storage means 10 are measured by an output sensor 13, and a signal K₁ from the output sensor 13 is inputted into the charging information processing section 25. Since charging of a lithium ion battery requires a particularly high level of precision of control with respect to the charging voltage, the first rapid charging control means 20 is configured to control charging at a high level of precision that takes this into account. The charging control unit 22 has a direct current chopper circuit using a step-up chopper circuit in conjunction with a step-down chopper circuit. A charging program for controlling optimal rapid charging of the first electric storage means 10 based on the detected first electric storage means 10 battery voltage and charging current is preinstalled in the charging information processing section 25.

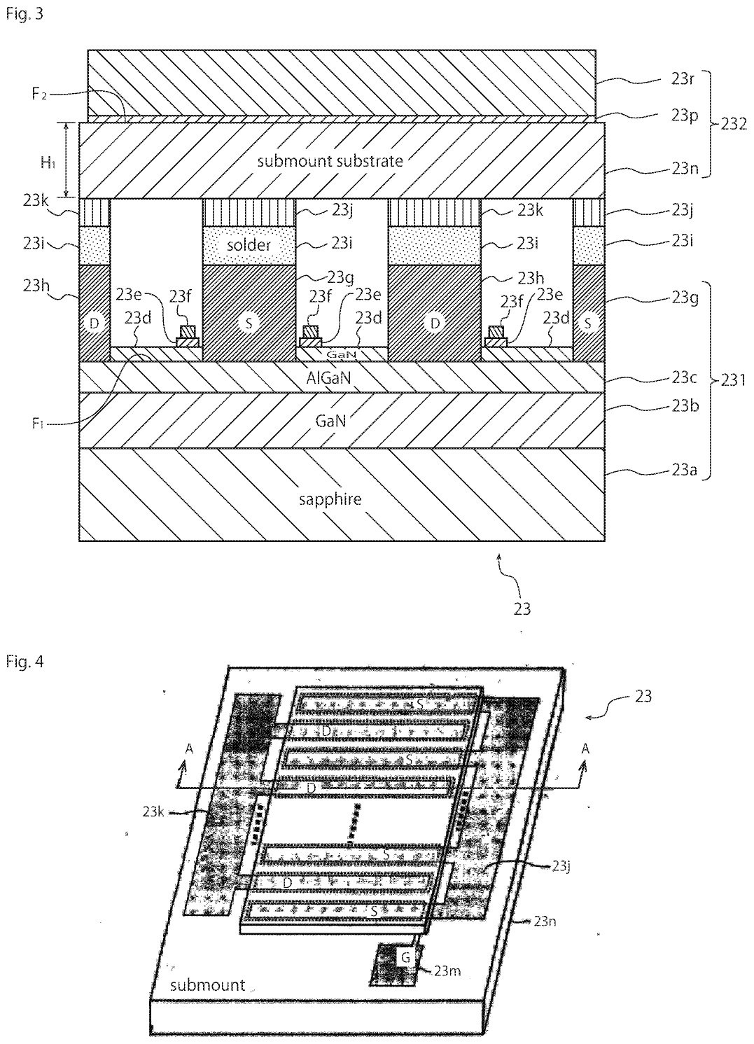

The power control section 21 of the first rapid charging control means 20 has a power semiconductor 23 for power conversion. The power semiconductor 23 uses a gallium nitride (GaN) semiconductor element to reduce loss during use at high temperatures and power conversion. FIGS. 3 to 6 depict the details of the power semiconductor 23, and FIG. 6 depicts the basic structure of the power semiconductor 23 using a gallium nitride (GaN) semiconductor element. For the power semiconductor 23, a gallium nitride power transistor 231 employing polarization super junction (PSJ) is formed on a sapphire substrate 23a. In this regard, super junction (SJ) refers to an approach of imparting a high pressure resistance/low on-resistance property employed in Si power MOS transistors. Polarization super junction (PSJ) refers to an approach of forming a super junction on a GaN transistor by utilizing a polarization effect due to GaN/AlGaN. The gallium nitride power transistor 231 employing polarization super junction in embodiment 1 has, for example, an excellent withstand voltage of 6000V and a switching frequency of about 1000 kHz (1 MHz), which is significantly higher compared to the switching frequency of conventional power semiconductors. Examples of gallium nitride semiconductors employing polarization super junction include those described in Japanese Patent No. 5669119.

As depicted in FIG. 6, the gallium nitride power transistor 231 is comprised of the sapphire substrate 23a to drain (D) 23h. First, a GaN film 23b is formed on the sapphire substrate 23a at the lowest level. Such a film and the films discussed below are formed, for example, by vapor deposition. An AlGaN film 23c is formed on the GaN film 23b. A source (S) 23g and drain (D) 23h are deposited on the surface of the AlGaN film 23c. A GaN film 23d is formed between the source S and the drain D on the outer surface of the AlGaN film 23c. A p-GaN film 23e is formed on the surface of the GaN film 23d. A p-ohmic metal (Ni/Au) is deposited on the surface of the p-GaN film 23e, and this p-ohmic metal film 23f constitutes gate G. By using the electrically insulating sapphire substrate 23a in the gallium nitride power transistor 231 employing polarization super junction in this manner, the restriction associated with withstand voltage for a substrate is eliminated, so that the thickness of GaN can be very thin as in about 1 μm, which is ⅕ compared to conventional substrates. This results in a GaN deposition time of about 2 hours, such that the deposition cost can be dramatically reduced compared to conventional technologies due to the reduction in manufacturing time.

As depicted in FIG. 4, the power semiconductor 23 using a gallium nitride semiconductor element has a plurality of sources S, drains D, and gates G. The sources S and drains D are each alternatingly disposed at a predetermined interval in the longitudinal direction in the Figure. The gates G are respectively disposed between the source S and the drain D. One of the patterning metal 23j has a function of electrically connecting a plurality of sources S in parallel as depicted on the right side of FIG. 4. The other patterning metal 23k has a function of electrically connecting a plurality of drains D in parallel as depicted on the left side of FIG. 4. Likewise, each gate G is electrically connected in parallel via another patterning metal 23m. This results in the power semiconductor 23 using a gallium nitride semiconductor element having a structure with a large number of gallium nitride power transistors 231 connected in parallel, such that a large amount of power can be controlled.

The heat dissipating structure of the power semiconductor 23 using a gallium nitride semiconductor element is now explained. The gallium nitride power transistor 231 employing polarization super junction in embodiment 1 has a wide band gap and can have a low on-resistance, but a heat dissipating property of the sapphire substrate 23a is low, which is about ¼ relative to an Si substrate. In this regard, the power semiconductor 23 employs heat dissipating means 232 for dissipating heat generated by power conversion outside to dissipate heat, instead of using the sapphire substrate 23a with a low heat dissipating property in the present invention. Heat involving power conversion is generated primarily at the interface between the GaN film 23b and the AlGaN film 23c in the gallium nitride power transistor 23. Thus, the heat dissipating means 232 is bonded to the outer surface of the source S region and the drain D region in the gallium nitride power transistor 231 to dissipate the heat generated from power conversion outside via the heat dissipating means 232.

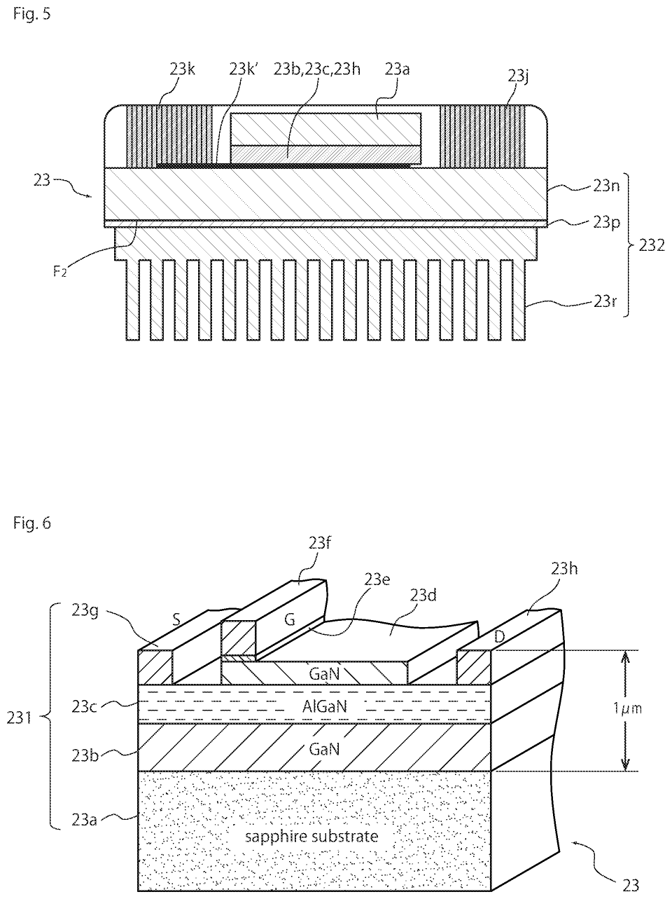

In embodiment 1, the heat dissipating means 232 is connected to at least one of the source S region and the drain D region on the outer surface of an element of the gallium nitride power transistor, and extends in a direction away from the sapphire substrate 23a. The heat dissipating means 232 is comprised of a submount substrate 23n, a metal sheet 23p, and a heat sink 23r, as depicted in FIGS. 3 and 5. The submount substrate 23n is comprised of, for example, silicon nitride (Si₃N₄), which is a material with insulating and excellent heat dissipating properties. The thickness H₁ of the submount substrate 23n is set to, for example, about 100 μm. In embodiment 1, the heat dissipating means 232 is connected to both the source S region and the drain D region on an outer surface F₁ of the AlGaN film 23c constituting the gallium nitride power transistor 231 via solder 23i and patterning metals 23j, 23k, and 23k′. Specifically, the source S region on the outer surface F₁ of the AlGaN film 23c is connected to the submount substrate 23n via the solder 23i and the patterning metal 23j. Likewise, the drain D region on the outer surface F₁ of the AlGaN film 23c is connected to the submount substrate 23n via the solder 23i and patterning metals 23k and 23k′.

A metal sheet 23p with high thermal conductivity is bonded to the entire surface of surface F₂ on the opposite side of where the gallium nitride power transistor 231 is located on the submount substrate 23n. This results in the majority of heat generated upon power conversion by the gallium nitride power transistor 231 being conducted to the metal sheet 23p. The heat sink 23r is bonded to the surface on the opposite side from the surface F₂ of the metal sheet 23p. The heat sink 23r is used for the purpose of dissipating heat, and is made of a metal material such as an aluminum alloy or copper alloy with an excellent thermal conductive property. The heat sink 23r is bonded to almost the entire surface of the submount substrate 23n with the metal sheet 23p interposed therebetween. A large number of projections called fins are formed to expand the surface area on the front end side of the heat sink 23r. The power semiconductor 23 can be packaged by covering the gallium nitride power transistor 231 and the heat dissipating means 232 with an insulation case (not shown), and is capable of controlling a large amount of power by being connected to an associated electric circuit. Air E for forced cooling is blown onto the power semiconductor 23 by a fan 32 depicted in FIG. 2 to increase the amount of heat dissipated from the gallium nitride power transistor 231.

The electric storage module 1 has a cooling unit 30 for cooling the charging system. The cooling unit 30 has a motor 31, the fan 32, and an electronic cooling element 33. The fan 32 is driven to rotate by the motor 31 to send air toward a cooling surface of the electronic cooling element 33 by the temperature control unit 24 receiving a control signal K₃ from the charging information processing section 25. The electronic cooling element 33 utilizes the Peltier effect and is configured to be operated by an external power supply. Since the power control section 21 controls a large amount of power supplied to the first electric storage means 10 during rapid charging, the temperature of a semiconductor element rises. The lithium ion batteries constituting the first electric storage means 10 are stored in close proximity to one another in relation to the storage space, so that the temperature rises during rapid charging. For this reason, the power control section 21 and the first electric storage means 10 are subjected to forced cooling by air sent from the cooling unit 30 during rapid charging. While the cooling structure using the electronic cooling element 33 is employed in embodiment 1, cooling may involve operating only the fan 32 or utilize a cooling structure employing a water cooling system using a heat exchanger.

In this manner, the size and weight of the first rapid charging control means 20 can be reduced by using the power semiconductor 23 using a gallium nitride semiconductor element in the first rapid charging control means 20, so that the first rapid charging control means 20 can be very easily installed in a small space. Since the power semiconductor 23 using a gallium nitride semiconductor element has a significantly higher power conversion efficiency compared to conventional power semiconductors using a silicon semiconductor element, heat generation from the first rapid charging control means 20 is low, so that the first rapid charging control means 20 can be sufficiently cooled even with a simple cooling unit 30 using the electronic cooling element 33 discussed above.

As depicted in FIGS. 1 and 2, the first rapid charging control means 20 has artificial intelligence 26 that optimally control a charging condition of the first electric storage means 10 based on the charging history of the first electric storage means 10. The artificial intelligence 26 is connected to the charging information processing section 25 and is configured to record results of charging (charging data such as charging voltage, charging current, or charging time during rapid charging) for each charging of the first electric storage means 10 by the first rapid charging control means 20. The artificial intelligence 26 and the charging information processing section 25 communicate information between each other via a signal K₆. The charging information processing section 25 is connected to a terminal T₃ for communicating information with an apparatus on the power source side. The first rapid charging control means 20 can estimate the lifespan of the first electric storage means 10 by knowing the number of charges and results of charging via the artificial intelligence 26. The artificial intelligence 26 also has a function of determining the presence or absence of an abnormality in the internal resistance value in a lithium ion battery constituting the first electric storage means 10, based on a signal K₂ from the output sensor 14. If it is determined that there is an abnormality, an instruction for forcing discontinuation of rapid charging is outputted via signals K₆ and K₇ to protect the first electric storage means 10 from overheating or the like. Information from the artificial intelligence 26 can be received at a data center (not shown) via wireless communication or the like, such that the operational status of the first electric storage means 10 can be found at all times at a data center, based on information from the artificial intelligence 26.

The operation and action of the electric storage module 1 in embodiment 1 are now explained.

Alternating current power from the alternating current power source 101 is converted to direct current power by the power converter 35 and supplied to the electric storage module 1. The electric storage module 1 has the first electric storage means 10 and the first rapid charging control means 20. Direction current power from the power converter 35 is supplied to the first electric storage means 10 via the first rapid charging control means 20. Some of the direct current power from the power converter 35 is controlled to have a charging voltage and a charging current that are compatible with the first electric storage means 10 by the charging control unit 22 of the power control section 21 in the first rapid charging control means 20. Some of the direct current power from the power converter 35 is supplied to the cooling unit 30 via the temperature control unit 24 in the first rapid charging control means 20.

Since the power control section 21 controls a large amount of power supplied during rapid charging of the first electric storage means 10, the temperature of the power semiconductor 23 in the power control section 21 rises. Further, lithium ion batteries constituting the first electric storage means 10 are stored in close proximity to one another in relation to the storage space, so that the temperature rises due to a charging current during rapid charging. In this regard, the power control section 21 and the first electric storage means 10 are subjected to forced cooling by air sent from the cooling unit 30 during rapid charging to suppress a rise in the temperature associated with rapid charging. Thus, the power control section 21 and the first electric storage means 10 are operated at an appropriate temperature within an acceptable range. The first electric storage means 10 uses at least a lithium ion battery, an electric double layer capacitor, and a lithium ion capacitor, so that the performance of accepting rapid charging in the first electric storage means 10 can be improved, which can shorten the charging time for the electric storage module 1.

Heat associated with power conversion is generated primarily at the interface between the GaN film 23b and the AlGaN film 23c in the gallium nitride power transistor 231 of the power semiconductor 23 in the present invention. Thus, the heat dissipating means 232 is bonded to the outer surface of the source S region and the drain D region in the gallium nitride power transistor 231 to dissipate the heat generated from power conversion to the outside via the heat dissipating means 232. In this regard, the heat sink 23r, which is one of the parts constituting the heat dissipating means 232, is bonded to almost the entire surface of the submount substrate 23n with the metal sheet 23p interposed therebetween. A large number of projections called fins are formed to expand the surface area on the front end side of the heat sink 23r. Air E for forced cooling is blown onto the power semiconductor 23 having the heat sink 23r by the fan 32 depicted in FIG. 2, so that a large amount of heat is exchanged via the heat sink 23r. This results in sufficient cooling of the power semiconductor 23, even when controlling a large amount of power associated with rapid charging of the first electric storage means 10, to prevent excessive rise in temperature.

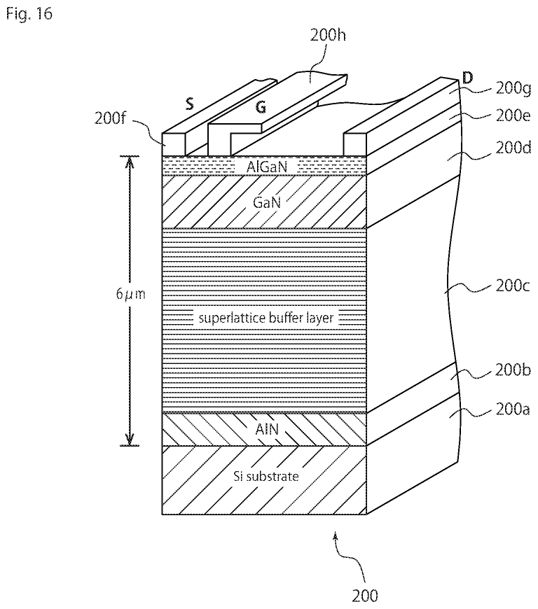

FIG. 16 depicts the structure of a conventional semiconductor using a gallium nitride semiconductor element. As depicted in FIG. 16, Si is the substrate in a conventional power semiconductor. An AlN film 200b is formed on an Si substrate 200a. A superlattice buffer layer 200c is formed on the surface of the AlN film 200b. A GaN film 200d is formed on the surface of the superlattice buffer layer 200c. An AlGaN barrier layer 200e is formed on the surface of the GaN film 200d. Each of the source (S) 200f, drain (D) 200g, and gate (G) 200h are formed on the surface of the AlGaN barrier layer 200e. The thickness of GaN in FIG. 16 is 6 μm, and the deposition time is 10 to 12 hours. In contrast, the gallium nitride power transistor 231 employing polarization super junction (PSJ) is formed on the sapphire substrate 23a in embodiment 1 as depicted in FIG. 6, so that the deposition time can be reduced to about 2 hours to significantly reduce the manufacturing cost.

The first rapid charging control means 20 may be configured to be capable of controlling a voltage and current for rapid charging which takes into account a charging property of the first electric storage means 10 by an integral design with the first electric storage means 10. Such a configuration can materialize a design that further matches the first electric storage means 10 and a charging control function. This enables the first electric storage means 10 to have an expected performance, so that the performance of the electric storage module 1 can be enhanced. By supplying high quality power such as pure direct current power to a load via the output terminal T₂, an electric circuit on the load side can be designed with the premise that high quality power is supplied. This facilitates the design of the electric circuit on the load side with hardly any need to take into account ripples, noises, or surges. The artificial intelligence 26 of the first rapid charging control means 20 has a function of determining the presence/absence of an abnormality in the internal resistance value in a lithium ion battery constituting the first electric storage means 10 based on the signal K₂ from the output sensor 14. If it is determined that there is an abnormality, an instruction for forcing discontinuation of rapid charging is outputted to protect the first electric storage means 10 from overheating or the like. Therefore, the safety and reliability of the electric storage module 1 in rapid charging can be enhanced.

In this manner, the gallium nitride power transistor 231 employing polarization super junction is formed on the sapphire substrate 23a, so that the power semiconductor 23 is capable of higher speed switching compared to conventional semiconductors using silicon. This also allows the reduction in size of parts constituting an electric circuit for operating the power semiconductor 23 in the first rapid charging control means 20. Furthermore, the heat dissipating means 232 for externally dissipating heat is bonded to the outer surface of an element of the gallium nitride power transistor 231, thus promoting dissipation of heat generated by power conversion. This enables the reduction in size of the structure for cooling the gallium nitride power transistor 231. Since the heat dissipating means 232 extends in the direction away from the sapphire substrate 23a, heat can be dissipated in the direction away from the sapphire substrate 23a to enhance the heat dissipating performance. In this manner, the electric storage module 1 can ensure safety and inhibition of deterioration in the electricity storage performance in rapid charging, and can significantly reduce the size of the first rapid charging control means 20. Thus, the electric storage module 1 can be readily integrated into various products to improve the usability of the products and operational efficiency. Furthermore, the first rapid charging control means 20 has the artificial intelligence 26 for optimally controlling the charging condition of the first electric storage means 10 based on the charging history of the first electric storage means 10, so that charging can be controlled in accordance with the deterioration of the first electric storage means 10 over time to extend the lifespan of the first electric storage means 10 while ensuring safety.

### Embodiment 2

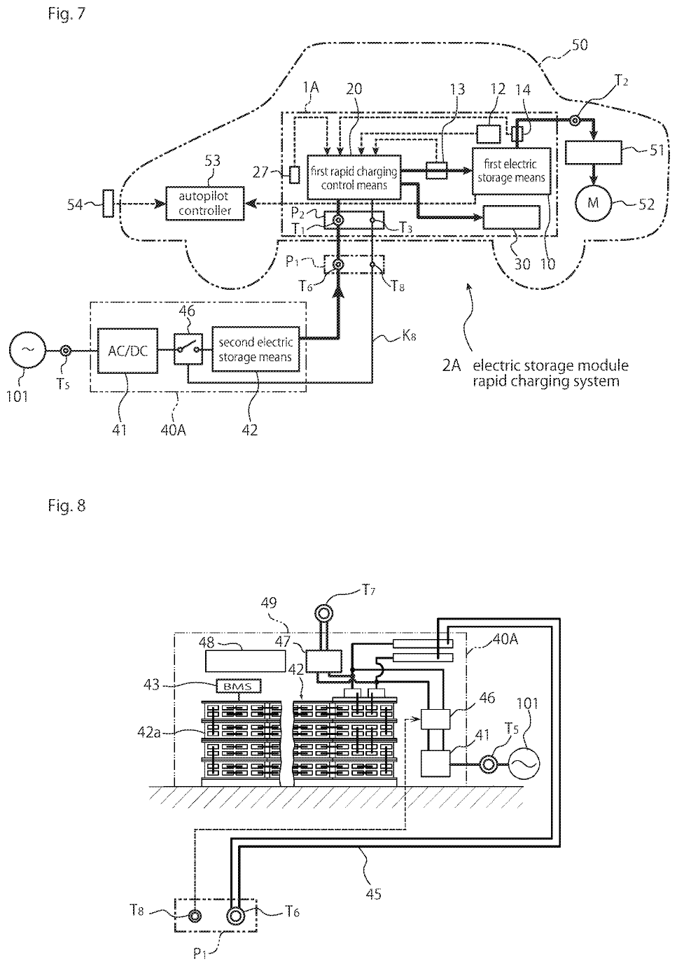

FIGS. 7 and 8 depict embodiment 2 of the invention and provide an example of integrating an electric storage module into a vehicle as an electrically powered mobile entity. The electric storage module 1A in FIG. 7 is the electric storage module in FIGS. 1 and 2 configured as a vehicle mounted electric storage module. Since the configuration and the function are in conformance with the electric storage module 1 in FIGS. 1 and 2, the same symbol as embodiment 1 is assigned to the portions in conformance to omit the explanation of the same portions. The same applies to the explanation in other embodiments discussed below. An electrically powered mobile entity includes at least vehicles, vessels, and aircrafts that are capable of moving by a motor, as well as self-propelled industrial machineries, robots, and the like.

FIG. 7 depicts an electric storage module rapid charging system 2A for rapidly charging the electric storage module 1A integrated into a vehicle 50. The electric storage module rapid charging system 2A comprises the electric storage module 1A integrated into the vehicle 50 side and a power storage apparatus 40A installed on the charging station side. The electric storage module 1A is disposed on the floor side of the vehicle 50 to lower the center of gravity of the vehicle 50. An inverter 51 is connected to the output terminal T₂ side of the first electric storage means 10 in the electric storage module 1A as a controller. The inverter 51 has a function of converting direct current power into alternating current power. A traveling motor 52 is connected to the output side of the inverter 51. Direct current power stored in the first electric storage means 10 can be supplied to the traveling motor 52 via the inverter 51. The vehicle 50 can travel with the traveling motor 52 as the driving source.

An autopilot controller 53 is installed in the vehicle 50. The autopilot controller 53 can be operated by the power supply from the first electric storage means 10. A sensor 54 for the autopiloting is connected to the autopilot controller 53. The sensor 54 has a function of recognizing the surroundings of the vehicle 50 during traveling. The vehicle 50 can operate without an operator. In other words, the autopilot controller 53 can automatically steer the vehicle 50 based on information from the sensor 54, three-dimensional digital map information transmitted from a data sensor, or the like to automatically travel along a determined route.

As depicted in FIG. 7, the power storage apparatus 40A has a second electric storage means 42, which can electrically connect to the electric storage module LA and store externally supplied power. The power storage apparatus 40A, when connected to the electric storage module 1A, can supply power from the second electric storage means 42 to the electric storage module 1A. As depicted in FIG. 7, the power storage apparatus 40A has a rectifier 41, the second electric storage means 42, and a power feeding control means 46. The alternating current power source 101 is connected to an input terminal T₅ of the rectifier 41. The rectifier 41 has the function of converting alternating current power to direct current power and charging the second electric storage means 42 under an appropriate condition. The second electric storage means 42 can be any type of means, as long as direct current power can be stored, but is comprised of at least one of a rechargeable battery, an electric double layer capacitor, and a lithium ion capacitor in embodiment 2. The second electric storage means 42 can be comprised of, for example, only a lithium ion battery configured as a large number of cells 42a connected in series or a configuration using a lithium ion battery in conjunction with a lithium ion capacitor. An output terminal T₆ for connection with the external load side is connected to the output side of the second electric storage means 42. A second battery management system (BMS) 43 for maintaining the charging balance of the large number of cells 42a constituting the second electric charging means 42 is connected to the second electric storage means 42.

The second electric storage means 42 of the power storage apparatus 40A has a greater electric storage capacity than the first electric storage means 10, and is capable of simultaneously charging a plurality of electric storage modules 1A with direct current power outputted from the second electric storage means 42. Specifically, in embodiment 2, the power storage apparatus 40A has the second electric storage means 42 for storing a large amount of power, so that a plurality of vehicles 50 can be simultaneously charged. An inverter 47 is connected to the second electric storage means 42 of the power storage apparatus 40A. The inverter 47 is connected to a smart meter (not shown) via a terminal T₇, and has a function of converting some of the direct current power stored in the second electric storage means to alternating current power and supplying the power to the household power side, based on an instruction from an electric utility company or the like. Each instrument constituting the power storage apparatus 40A is housed, for example, in a storage room 49 having the same size as an ocean shipping container. The temperature and humidity are adjusted to be within a certain range throughout the year with an air conditioner 48 inside the storage room 49.

The first rapid charging control means 20 may be configured to be capable of controlling a voltage and current for rapid charging which takes into account a charging property of the first electric storage means 10 by an integral design with the first electric storage means 10. If such control is enabled, a charging property of the first electric storage means 10 can be sufficiently taken into account by the integral design, so that charging can be controlled at a high level of precision to extend the lifespan of the first electric storage means 10 and further ensure safety. Since rapid chargers installed on the charging station side and secondary batteries installed in vehicles for conventional electric cars are generally manufactured by different manufacturers for conventional electric cars, it was challenging for the designers of rapid chargers to thoroughly understand the properties of secondary batteries installed in vehicles. For this reason, it was challenging to control charging at a high level of precision while sufficiently taking into account the charging property of a secondary battery installed in a vehicle for conventional rapid charging systems for electric cars, which presented problems such as ensuring lifespan or safety of secondary batteries. However, such problems can also be solved by such controlling of charging.

The procedure and action of rapid charging of vehicles in embodiment 2 are now explained.

When the vehicle 50 arrives at a charging station, the vehicle 50 is parked in the vicinity of the power storage apparatus 40A. Prior to commencing charging, the operation switch of the vehicle 50 is turned off, and the vehicle 50 is immobilized at a parking position with the parking brake. A charging plug P₁ at the tip of a charging cable 45 connected to the second electric storage means 42 of the power storage apparatus 40A is plugged into a charging connector P₂ of the vehicle 50. Immediately prior to commencing charging, a control signal K₆ is outputted from the vehicle 50 side to the power feeding control means 46 of the power storage apparatus 40A via terminals T₃ and T₈ connected by plugging the charging plug P₁ into the charging connector P₂, and power supply from the rectifier 41 to the second electric storage means 42 is stopped by the power feeding control means 46. This cuts off the second electric storage means 42 from the household power source 101 to enable a large amount of power for rapidly charging the vehicle 50 to be supplied from the second electric storage means 42.

In this manner, the first electric storage means 10 can be rapidly charged by utilizing direct current power that is directly delivered from the second electric storage means 42 of the external power storage apparatus 40A, so that overloading of the power distribution system of an electric utility company can be avoided, and power for rapidly charging the first electric storage means 10 can be dramatically increased. This allows full charging of the electric storage module 1A in a short period of time to enhance the efficiency of the charging operation. Since the charging time of the electric storage module 1A is reduced, waiting time for charging of the vehicle 50 can be avoided, which enables higher turnover rate for the use of charging stations.

### Embodiment 3

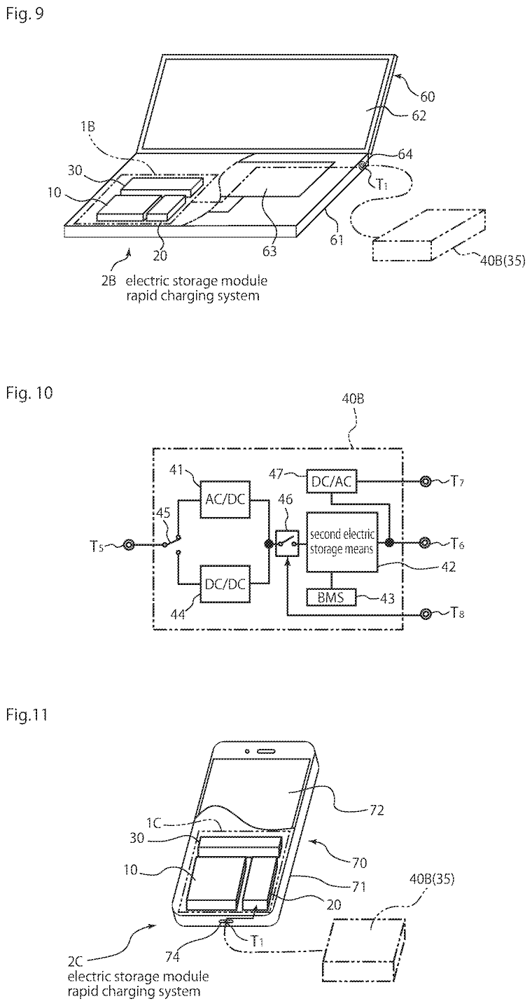

FIGS. 9 and 10 depict embodiment 3 of the invention and provide an example of integrating the electric storage module 1 depicted in FIGS. 1 and 2 into a personal computer 60 used as a mobile entity for communication. The electric storage module 1B in FIG. 9 is a dedicated electric storage module for the personal computer 60 comprising the same features as the electric storage module 1 in FIGS. 1 and 2. The configuration and the function thereof are in conformance with the electric storage module 1 in FIGS. 1 and 2.

FIG. 9 depicts an electric storage module rapid charging system 2B for rapidly charging the electric storage module 1B that is integrated into the personal computer 60. The personal computer 60 has a main body section 61 and a display section 62. The display section 62 is foldable to the main body section 61 side. A keyboard 63 for inputting information is provided to the main body section 61. An input terminal T₁ of the electric storage module 1B is provided in a connection port 64 formed on a side surface of the main body section 61. The electric storage module rapid charging system 2B comprises the electric storage module 18 integrated into the main body section 61 side of the personal computer 60 and a portable power storage apparatus 40B, which can connect to the personal computer 60. The power storage apparatus 40B has a reduced size and weight so as to be portable just like the personal computer 60. The function thereof is in conformance with the function of the power storage apparatus 40A depicted in FIG. 7 or 8. The power storage apparatus 40B differs from the power storage apparatus 40A with respect to the type of input power source. The input power source is only alternating current power sources for the power storage apparatus 40A, whereas a power converter 44 consisting of a DC-DC converter is added to the power storage apparatus 40B to enable input from a direct current power source. The type of input power source in the power storage apparatus 40B is configured to be switchable with a switch 45.

In embodiment 3 configured in this manner, the first electric storage means 10 can be rapidly charged by utilizing direct current power that is directly delivered from the second electric storage means 42 of the external power storage apparatus 40B, so that overloading of the indoor wiring at home or office can be avoided, and power for rapidly charging the first electric storage means 10 can be dramatically increased. This allows full charging of the electric storage module 1B in a short period of time to enhance the efficiency of charging operation. If the power consumption for rapid charging of the personal computer 60 is low and it is possible to ensure that overloading of indoor wiring at home or office can be avoided without using the power storage apparatus 40B, the power converter 35 in FIG. 1 for converting alternating current power into direct current power can also be used in place of the power storage apparatus 40B.

### Embodiment 4

FIG. 11 depicts embodiment 4 of the invention and provides an example of integrating the electric storage module 1 in FIGS. 1 and 2 into a smartphone 70, which is one type of mobile phones, used as a mobile entity for communication. The electric storage module 1C in FIG. 11 is a dedicated electric storage module for the smartphone 70 comprising the same features as the electric storage module 1 in FIGS. 1 and 2. The configuration and the function are in conformance with the electric storage module 1 in FIGS. 1 and 2. FIG. 11 depicts an electric storage module rapid charging system 2C for rapidly charging the electric storage module 1C that is integrated into the smartphone 70. The smartphone 70 has a main body section 71 and an operation section 72. The operation section 71 comprises both an input function for inputting information and a display function for displaying information. An input terminal T₁ of the electric storage module 1C is provided in the connection port 74 formed on a side surface of the main body section 71. The electric storage module rapid charging system 2C comprises the electric storage module 1C and the power storage apparatus 40B. The power storage apparatus 40B can be used, and is designed to be used, in both the personal computer 60 and the smartphone 70.

In embodiment 4 configured in this manner, the first electric storage means 10 can be rapidly charged by utilizing direct current power that is directly delivered from the second electric storage means 42 of the external power storage apparatus 40B, so that power for rapidly charging the first electric storage means 10 can be dramatically increased. This allows fully charging the electric storage module 1C in a short period of time to enhance the efficiency of charging operation. If the power consumption for rapid charging of the smartphone 70 is low and it is possible to ensure that overloading of indoor wiring at home or office can be avoided without using the power storage apparatus 40B, the power converter 35 in FIG. 1 for converting alternating current power into direct current power can also be used.

### Embodiment 5

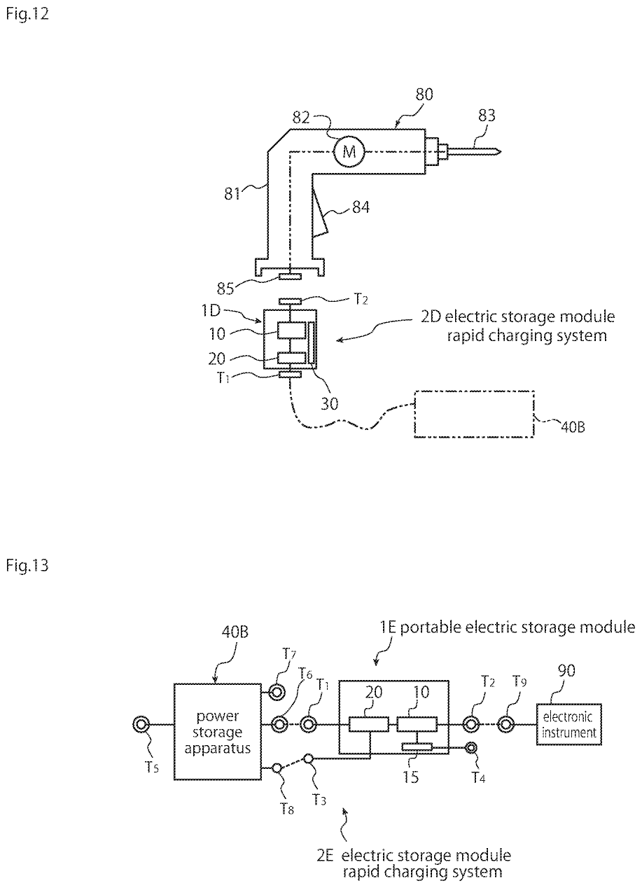

FIG. 12 depicts embodiment 5 of the invention and provides an example of integrating the electric storage module 1 in FIGS. 1 and 2 into an electric power tool 80. The electric storage module D in FIG. 12 is a dedicated electric storage module for the electric power tool 80 comprising the same features as the electric storage module 1 in FIGS. 1 and 2. The configuration and the function are in conformance with the electric storage module 1 in FIGS. 1 and 2. FIG. 12 depicts an electric storage module rapid charging system 2D for rapidly charging the electric storage module 1D that is integrated into the electric power tool 80. The electric storage module rapid charging system 2D comprises the electric storage module 1D and the power storage apparatus 40B. The electric storage module 1D is detachable from a main body section 81 of the electric power tool 80. A motor 82 is stored in the main body section 81 of the electric power tool 80. A drill 83 is configured to rotate about the axial center due to the rotational drive of the motor 82 by the operation of a switch 84.

In embodiment 5 configured in this manner, the electric storage module 1D is detached from the main body section 81 when charging the electric storage module 1D. The electric storage module 1D is then electrically connected to the portable power storage apparatus 40B to rapidly charge the first electric storage means 10 of the electric storage module 1D by utilizing direct current power that is directly delivered from the second electric storage means 42 of the power storage apparatus 40B. Once rapid charging of the electric storage module 1D is completed, the electric storage module 1D is again attached to the main body section 81 of the electric power tool 80. Terminal T₂ of the electric storage means 1D is connected to a terminal 85 of the electric power tool 80, and power of the first electric storage means 10 of the electric storage module 1D is supplied to the motor 82 via the terminal T₂ of the electric storage module 1D and the terminal 85 of the electric power tool 80, so that the electric power tool 80 can be used. In this manner, power for rapidly charging the electric storage module 1D of the electric power tool 80 can be dramatically increased compared to charging of conventional electric power tools, so that the electric storage module 1D can be fully charged in a short period of time by using the power storage apparatus 40B. This enables increased efficiency of the operation to charge the electric power tool 80 to reduce the operational time using the electric power tool 80.

### Embodiment 6

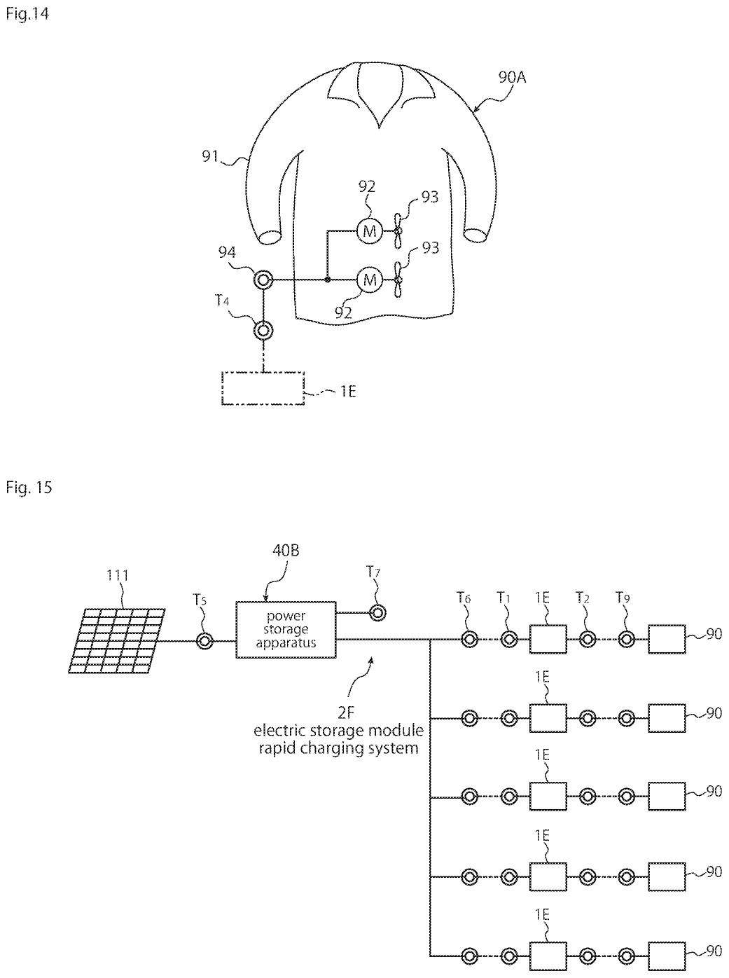

FIGS. 13 and 14 depict embodiment 6 of the invention and provide an example utilizing the electric storage module 1 in FIGS. 1 and 2 as a portable electric storage module 1E. An electric storage module rapid charging system 2E of the portable electric storage module 1E depicted in FIG. 13 comprises the portable electric storage module 18 and the power storage apparatus 40B. The portable electric storage module 1E and the power storage apparatus 40B can be separated. For example, the power storage apparatus 40B is always placed at a specific location in a room, and only the portable electric storage module 1E can be portably transported outside. The portable electric storage module 1E has a function of supplying power to, for example, various electronic instruments 90. The input terminal T₁ of the portable electric storage module 1E is electrically connected to the output terminal T₆ of the electric storage apparatus 40B during rapid charging of the portable electric storage module 1E by the power storage apparatus 40B. During rapid charging of the portable electric storage module 1E, a signal terminal T₃ of the portable electric storage module 1E is electrically connected to the signal terminal T₈ of the power storage apparatus 40B and exchanges information for controlling rapid charging via a signal passing between the terminals. The signal terminal T₃ and the signal terminal T₈ are connected, for example, in concert with an operation to connect the input terminal T₁ and the output terminal T₆.

The portable electric storage module 1E separated from the power storage apparatus 40B can be portably transported outside or the like, and can electrically connect to various electronic instruments 90. When supplying power to various electronic instruments 90 with the portable electric storage module 1E separated from the power storage apparatus 40B, an input terminal T₉ of the electronic instrument 90 is electrically connected to the output terminal T₂ of the portable electric storage module 1E, as depicted in FIG. 13. This enables power to be supplied from the portable electric storage module 1E to the electronic instrument 90. Once supplying of power to the electronic instrument 90 with the portable electric storage module 1E is completed, the portable electric storage module 1E is separated from the electronic instrument 90. This enables the portable electric storage module 1E to be portably transported independently.

Specific examples of the electronic instrument 90 include air conditioned clothing 90A and the like. FIG. 14 depicts, the air conditioned clothing 90A as an electronic instrument. The air conditioned clothing 90A is comprised of a light material 91 with chemical fibers interwoven therein. The front side can be opened and closed with a zipper (not shown). A cooling fan 93 is provided on both lower side portions of the air conditioned clothing 90A. The cooling fan 93 is configured so that the amount of air blown for cooling can be adjusted by changing the number of rotations by changing the voltage applied to a motor 92. The motors 92 for rotating the respective cooling fans 93 are electrically connected in parallel. An input terminal 94 for supplying power to each motor 92 is provided on the front surface side of the material 91 of the air conditioned clothing 90A. The input terminal 94 of the air conditioned clothing 90A can be connected to the output terminal T₄ of the portable electric storage module 1E. When supplying power to the air conditioned clothing 90A with the portable electric storage module 1E, an output switch (not shown) provided on the portable electric storage module 1E depicted in FIG. 13 is switched to the power converter 15 side. In this state, a voltage of direct current power supplied to the motor 92 for rotatably driving each of the cooling fans 93 can be adjusted stepwise by controlling of the power converter 15. In embodiment 6, a voltage applied to the motor 92 is set to, for example, three levels, where a higher voltage increases the amount to air blown for cooling. An example with two motors 92 and two cooling fans 93 has been explained in this embodiment, but embodiment 6 is not limited to these numbers. Embodiment 6 can also be applied to embodiments with one motor 92 and one cooling fan 93, embodiments with 3 or more motors 92 and cooling fans 92, or embodiments with different numbers of motors 92 and cooling fans 93.

### Embodiment 7

FIG. 15 depicts embodiment 7 of the invention. The electric storage module rapid charging system 2F depicted in FIG. 15 comprises one power storage apparatus 40B and a plurality of portable electric storage modules 1E. The system is installed in a room at home or office. As depicted in FIG. 15, the input terminal T₅ of the power storage apparatus 40B is configured so that power generated using renewable energy is inputted. The example depicted in FIG. 15 uses sun light as the renewable energy, and a solar cell panel 111 capable of generating electricity from sun light is connected to the input terminal T₅ of the power storage apparatus 40B, but renewable energy other than sun light can also be used. A plurality of output terminals T₆ are provided on the output side of the power storage apparatus 40B. The plurality of output terminals T₆ are each connected in parallel. In embodiment 7, five output terminals T₆ are provided. The portable electric storage module 1E can be connected to each of the five output terminals T₆. As depicted in FIG. 15, the electric storage module rapid charging system 2F can rapidly charge five portable electric storage modules 1E simultaneously with a single power storage apparatus 403. The electric storage capacity of the second electric storage means 42 of the power storage apparatus 40B is set to a significantly greater amount than that for the first electric storage means 10 of the portable electric storage module 1E by taking into account that five portable electric storage modules 1E are rapidly charged simultaneously.

When rapidly charging a plurality of portable electric storage modules 1E simultaneously in embodiment 7 configured in this manner, the input terminals T₁ of the portable electric storage modules 1E are respectively connected to the plurality of the output terminals T₆ of the power storage apparatus 40B. In this state, the electronic instrument 90 is not connected to the output terminal T₂ of each portable electric storage module 1E. In addition, the five portable electric storage modules 1E are rapidly charged simultaneously by the supply of pure direct current power from the output of pure direct current power to each of the portable electric storage module 1E via the output terminals T₆ of the power storage apparatus 40B. In this manner, the electric storage capacity of the second electric storage means 42 of the power storage apparatus 40B is set to be significantly greater than that of the first electric storage means 10 of the portable electric storage module 1B, so that the plurality of portable electric storage module 1E can be charged simultaneously with direct current power outputted from the second electric storage means 42 to enhance the efficiency of charging operation.

Once the simultaneous rapid charging of the plurality of portable electric storage modules 1E is completed, each of the portable electric storage modules 1E is separated from the power storage apparatus 40B and becomes portably transportable outdoors. Each of the portable electric storage modules 1E portably transported outside is used when supplying power to various electronic instruments 90. In this regard, the first rapid charging control means 20 for converting direct current power that is directly delivered from the power storage apparatus 40B into power that is suitable for rapid charging of the first electric storage means 10 is provided to each of the portable electric storage modules 1E, as depicted in FIG. 13. Thus, each of the portable electric storage modules 1E is rapidly charged under optimal charging conditions, such that safety can be ensured against rapid charging, and lifespan of the first electric storage means 10 can be extended. The degree of deterioration of the first electric storage means 10 varies between new portable electric storage modules 1E and those used over the years. However, since the first rapid charging control means 21 is provided for each portable electric storage module 13, charging is controlled optimally in alignment with the degree of deterioration of the first electric storage means 10 for each portable electric storage module 1E, which ensures safety in rapid charging. In embodiment 7, power stored in the power storage apparatus 40B is power generated using renewable energy, i.e., sun light. Thus, carbon dioxide emission from power generation can be prevented to contribute to minimization of global warming. Furthermore, first electric storage means can be rapidly charged by utilizing direct current power that is directly delivered from second electric storage means of an external power storage apparatus, so that overloading of the indoor wiring at home or office can be avoided, and power for rapidly charging the first electric storage means can be dramatically increased. This allows full charging of an electric storage module in a short period of time to enhance the efficiency of charging operation.

While embodiments 1 to 7 of the invention have been discussed above in detail, specific configurations are not limited to these embodiments. Configurations with a design change or the like that remain within the spirit of the invention are encompassed by the invention. For example, embodiments 1 to 7 have explained gallium nitride power semiconductors employing polarization super junction, but the power semiconductor of the invention can be any power semiconductor, which has a gallium nitride power transistor formed on a sapphire substrate and comprises heat dissipating means for dissipating heat generated by power conversion on an outer surface of an element of the gallium nitride power transistor. The power semiconductor can be those that do not employ polarization super junction. For example, embodiments 1 to 7 have also explained electric storage modules with a configuration comprising a cooling unit, but the electric storage module of the invention can be those that do not comprise a cooling unit. For example, a cooling unit can be provided externally to the electric storage module. A cooling unit does not need to be provided if heat generated by the electric storage module is low. For example, embodiments 1 to 7 have also explained inventions comprising artificial intelligence, but the present invention is also applicable to inventions that do not comprise artificial intelligence. For example in embodiments 1 to 7, there are two types of output of an electric storage module, i.e., an output via T₂ and an output via T₄, but the present invention is not limited to such a configuration. The configuration can have only one of the outputs. For example, the alternating current power source 101 is used in embodiments 1 to 6, and renewable energy is used in embodiment 7 as a power supply source, but the present invention is not limited to a specific power supply source. Renewable energy can be used in embodiments 1 to 6, and the alternating current power source 101 can be used in embodiment 7. For example, the electronic instrument 90 includes those discussed above as well as portable communication instruments such as transceivers, drones, robots, agricultural equipment, and the like. The portable electric storage module 1Z can be configured, for example, in a size that can be portably transported in one hand, or in a size of a suitcase comprising a mobility wheel.

### REFERENCE SIGNS LIST

1 Electric storage module
1A Electric storage module (electric storage module for electric cars)
1B Electric storage module (electric storage module for personal computers)
1C Electric storage module (electric storage module for smartphones)
1D Electric storage module (electric storage module for electric power tools)
1E Electric storage module (portable electric storage module for electric cars)
2A Electric storage module rapid charging system (rapid charging system for electric cars)
2B Electric storage module rapid charging system (rapid charging system for personal computers)
2C Electric storage module rapid charging system (rapid charging system for smartphones)
2D Electric storage module rapid charging system (rapid charging system for electric power tools)
2E Electric storage module rapid charging system (rapid charging system for portable electric storage modules)
2F Electric storage module rapid charging system
10 First electric storage means
20 First rapid charging control means
23 Power semiconductor
231 Gallium nitride power transistor
23a Sapphire substrate
232 Heat dissipating means
26 Artificial intelligence
30 Cooling unit
40A Power storage apparatus (Power storage apparatus for rapidly charging electric cars)
40B Power storage apparatus (Power storage apparatus for rapidly charging electronic instruments)
42 Second electric storage means
50 Vehicle (electrically powered mobile entity)
60 Personal computer (mobile entity for communication)
70 Smartphone (mobile entity for communication)
80 Electric power tool
90 Electronic instrument
90A Air conditioned clothing

1.-11. (canceled)

12. An electric storage module comprising:
a first electric storage means; and
a first rapid charging control means, which has a power semiconductor for power conversion and applies power conversion on externally supplied power to rapidly charge the first electric storage means, and wherein heat generated from power conversion is dissipated outside via heat dissipating means.

13. The electric storage module of claim 12, wherein the first electric storage means includes all-solid state battery.

14. The electric storage module of claim 12, wherein the power semiconductor is capable of higher speed switching compared to a semiconductor using silicon.

15. The electric storage module of claim 12, wherein the first rapid charging control means is configured to be capable of controlling a voltage and a current for rapid charging which takes into account a charging property of the first electric storage means by an integral design with the first electric storage means.

16. The electric storage module of claim 12, wherein the first electric storage means comprises at least one of a lithium ion battery, an electric double layer capacitor, and a lithium ion capacitor.

17. The electric storage module of claim 12, wherein the first rapid charging control means has artificial intelligence for optimally controlling a charging condition of the first electric storage means based on a charging history of the first electric storage means.

18. The electric storage module of claim 12, wherein the first electric storage means and the first rapid charging control means are configured to be integrated into at least electrically powered mobile entities including vehicles or mobile entities for communication including mobile phones.

19. The electric storage module of claim 12, further comprising a power converter for adjusting and outputting a voltage of direct current power that is outputted from the first electric storage means.

20. The electric storage module of claim 12, wherein the power semiconductor comprises a sapphire substrate and a gallium nitride power transistor formed on the sapphire substrate, and wherein the heat dissipating means is bound to an outer surface of an element of the gallium nitride power transistor.

21. The electric storage module of claim 20, wherein the power semiconductor is a power semiconductor employing polarization super junction.

22. The electric storage module of claim 20, wherein the heat dissipating means is connected to at least one of a source region and a drain region on the outer surface of an element of the gallium nitride power transistor and extends in a direction away from the sapphire substrate.

23. An electric storage module rapid charging system comprising:
a first electric storage means;
a first rapid charging control means, which has a power semiconductor for power conversion and applies power conversion on externally supplied power to rapidly charge the first electric storage means, and wherein heat generated from power conversion is dissipated outside via heat dissipating means; and
a power storage apparatus having second electric storage means which is electrically connectable to the electric storage module, wherein the power storage apparatus is configured to be able to supply power, when connected to the electric storage module, from the second electric storage means to the electric storage module.

24. The electric storage module rapid charging system of claim 23, wherein the second electric storage means of the power storage apparatus has a greater electric storage capacity than the first electric storage means, and is capable of simultaneously charging a plurality of the electric storage modules with direct current power outputted from the second electric storage means.

25. The electric storage module rapid charging system of claim 23, wherein power stored in the power storage apparatus is power generated using renewable energy.
